(19) United States
(12) Patent Application Publication
(10) Pub. No.: US 2026/0254402 A1
(43) Pub. Date: Aug. 27, 2026

(54) ADJUSTABLE MODULAR AND DIGITAL PHOTOVOLTAIC CLADDING SYSTEM

(71) Applicant: Antonio BENEDUCE, NAPOLI (IT)

(72) Inventor: Antonio BENEDUCE, NAPOLI (IT)

(21) Appl. No.: 19/483,784

(22) PCT Filed: May 10, 2023
(86) PCT No.: PCT/IB2023/054826

§ 371 Date: Nov. 12, 2025

(51) Int. Cl. H02S 20/30; E04D 1/30; E04F 13/072; G09F 9/33

(52) U.S. Cl. CPC H02S 20/30; E04D 1/30; E04F 13/072; G09F 9/33; E04D 2001/308

(57) ABSTRACT

An adjustable modular and digital cladding photovoltaic system (1) is described, designed to produce electricity obtained from solar energy and to project digital contents, on the surface of a building to be covered, the system (1) being capable of rotating by an angle α with 0°≤α≤360° thus allowing the coating of external and roofing surfaces, with variable dimensions, extensions and inclinations.

The present invention relates to a modular and digital photovoltaic cladding system, in particular an adjustable modular and digital photovoltaic coating and cladding system.

The use of renewable energy to reduce electricity acquisition costs and environmental impact is known, because it allows to be self-sufficient and eco-sustainable. It is known that for solar plants the amount of energy produced depends on the season and on the system exposure to the sun rays: consequently, during the hot summer months, it will be higher than in winter. In order to optimize the efficiency of these systems, concentrated photovoltaic systems are used. These types of systems represent an evolution of traditional photovoltaics, because they are able to make better use of the sun rays, managing to produce a greater quantity of energy with the same surface. The main characteristics of these types of systems can be traced back to the use of mirrors or lenses with which they concentrate light and direct light towards high-efficiency photovoltaic cells. In particular, document CN203594186 indicates a system with panels installed on the external walls of buildings, said panels being equipped with LED devices and solar devices. Said panels comprise: an outer surface layer, a heat preservation layer, a moisture impermeable layer and a flame retardant layer.

Advantageously, the system is also equipped with a storage battery, which stores energy from the solar device and, if necessary, powers the LED devices which can emit light of different colors.

Also known is document EP3316478, which refers to a plurality of associated elements within the same physical area, such as for example a panel; in particular, said elements are: renewable energy modules, construction elements and constructions which allow to use different functions and to interact when necessary.

Furthermore, a document CN105649290 is known which describes decorative coatings for external walls, such coating consisting of layers of elements, which include glass, adhesives, solar battery sets, LED lamp bars. The peculiarity of these coatings is that they meet the technical requirements of building materials for thermal insulation, sound insulation and fire prevention.

Also known is a document US2013153519, which describes a solar tracker and more precisely a modular support group for a solar tracker which allows reduced assembly and transport costs.

It is evident that there are no modular and digital photovoltaic cladding systems capable of cladding the external and roofing surfaces of buildings, stadiums, etc. with variable dimensions, extensions and inclinations, wherein these cladding element are equipped with: photovoltaic devices; lighting and light projection devices; energy storage devices; solar tracking devices; panel movement devices advantageously capable of covering the external and roofing surfaces of buildings, stadiums, etc. with variable dimensions, extensions and inclinations allowing a dual function of solar energy recovery in an optimized way, of projection of digital contents and of be integrated through computers on site or remotely.

Object of the present invention is solving the aforesaid prior art problems by providing an adjustable modular and digital photovoltaic cladding system, capable of producing electric energy obtained from solar energy and of projecting digital content onto the surface of the building to be clad with any inclination.

Another object of the present invention is providing an adjustable modular and digital photovoltaic cladding system equipped with a remote control device using AI technology.

The above and other objects and advantages of the invention, as will appear from the following description, are achieved with an adjustable modular and digital photovoltaic cladding system such as claimed in claim 1. Preferred embodiments and non-trivial variations of the present invention form the subject matter of the dependent claims.

It is understood that all attached claims form an integral part of the present description.

It will be immediately obvious that innumerable variations and modifications (for example relating to shape, dimensions, arrangements and parts with equivalent functionality) can be made to what has been described, without departing from the scope of the invention as appears from the attached claims.

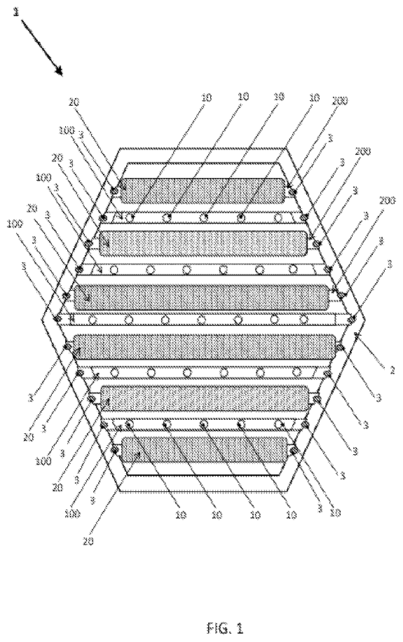

The present invention will be better described by some preferred embodiments thereof, provided by way of non-limiting example, with reference to the attached drawings, in which FIG. 1 shows a front view of a preferred embodiment of the system according to the present invention.

With reference to the Figure, an adjustable modular and digital photovoltaic cladding system 1 is shown, designed to produce electricity obtained from solar energy and to project digital contents, such as, for example, entertainment videos, advertising writings, colored images, etc. on the surface of a building to be covered, such as, for example, a building, a stadium, etc. . . . , allowing the system 1 to rotate by an angle α with 0°≤α≤360°, thus allowing the coating of external and roofing surfaces, with variable dimensions, extensions and inclinations. Advantageously, the modular and digital photovoltaic cladding system 1 according to the present invention comprises:
a plurality of LEDs 10, such as for example package LEDS (DIP, Dual in Line Package), or surface mount LEDS (SMD, Surface Mount Device), or other suitable ones, spaced out (pixel pitch) according to the resolution to be obtained and of the viewing distance and inclination at which the system 1 will be placed, arranged on a first plurality of horizontal bars 100;
at least one strip of photovoltaic cells 20, preferably made of aluminum, having a suitable shape, to adapt to the external and roofing surfaces of the building to be covered, arranged on the front surface of a second plurality of horizontal bars 200;
a plurality of detection and control sensors, designed to control brightness, contrast and chromatic range, of the plurality of LEDs 10;
an aluminum perimeter structure 2;
the first plurality of horizontal bars 100, preferably made of aluminum, preferably with a round or square profile, internally connected with each end to the perimeter structure 2 by means of a joint element 3, preferably made of Teflon®, and equipped with at least one movement device capable of inducing a slow rotation of each first plurality of horizontal bars 100 by an angle α, included in a range 0°≤α≤360°, and provided on the front surface with a plurality of holes designed to enable housing the plurality of LEDs 10;
the second plurality of horizontal bars 200, preferably made of aluminum, preferably with a round or square profile, internally connected with each end to the perimeter structure 2 by means of a joint element 3, preferably made of Teflon®, and equipped with at least one movement device capable to induce a slow rotation of each plurality of horizontal bars by an angle α, included in a range 0°≤α≤360°, and provided on the front surface of the strip of photovoltaic cells;
a remote control device capable of regulating and remotely controlling, using AI technology, the plurality of sensors, and each movement device, enabling a rotation of the first 100 and of the second 200 plurality of horizontal bars and consequently of the strip of photovoltaic cells and of the plurality of LEDS 10 according to a plurality of factors, such as weather conditions, direct or indirect sunlight, etc.;
at least one insulated compartment arranged on the back surface of the first 100 and second 200 plurality of horizontal bars, designed to contain a plurality of electrical elements and devices dedicated to remote management.

Advantageously, the first plurality of bars 100 and the second plurality of bars 200 are arranged alternately, enabling an independent rotation, with concordant or discordant rotation direction, of each plurality of LEDS 10, and of each strip of photovoltaic cells 20 arranged respectively on the first 100 and on the second 200 plurality of horizontal bars, improving the performance of the projected multimedia content, and decreasing energy expenditure.

Furthermore, this first plurality of bars 100 is internally equipped with electronic devices, such as, for example, integrated chips, PCB boards, etc., dedicated to the electrical operation of the plurality of LEDS 10, allowing the system 1 to project digital contents onto the external surfaces and/or roofing of the building to be covered.

In a second embodiment, the system 1 comprises:
the plurality of LEDs 10
at least one photovoltaic module, such as for example a solar digital LED, a transparent photovoltaic module, or the like, equipped with a plurality of photovoltaic cells, preferably made of aluminum, having a suitable shape, such as, for example, hexagonal, rectangular, or square, to adapt to the external and roofing surfaces of the building to be covered;
a plurality of detection and control sensors, designed to control brightness, contrast and chromatic range of the plurality of LEDs 10;
an aluminum perimeter structure 2;
a plurality of aluminum bars 300, preferably with a round or square profile, arranged on the front surface of the photovoltaic module and equipped on the front surface with a plurality of holes designed to enable housing the plurality of LEDs, equipped internally connected with each end to the perimeter structure by means of the articulation element 3, preferably made of Teflon®, and equipped with at least one movement device capable of inducing a slow rotation of each first plurality of horizontal bars 100 by an angle α, included in a range 0°≤α≤360°, inducing the rotation of the photovoltaic panel and of the plurality of LEDs 10;
the remote control device capable of remotely regulating and controlling the plurality of sensors, and each movement device, consequently enabling the rotation of the photovoltaic panel and of the plurality of LEDS 10 according to a plurality of factors, such as weather conditions, direct or indirect sunlight, etc.;
the insulated compartment arranged on the back surface of the plurality of horizontal bars 300 designed to contain a plurality of electrical elements and devices dedicated to remote management.

In a third embodiment, the system 1 further comprises:
at least one transparent photovoltaic module;
a plurality of bars arranged on the rear surface of the transparent photovoltaic module, internally connected with each end to the perimeter structure by means of a joint element 3, preferably made of Teflon®, and equipped with a movement device capable of inducing a slow rotation of each plurality of horizontal bars by an angle α, included in a range 0°≤α≤360°, and consequently to induce a rotation of the transparent photovoltaic module.

The 360° rotation of the plurality of horizontal bars allows to use the system in any inclination, even upside down, providing an internal or external covering, increasing the visibility angle β of the multimedia contents transmitted by the system, with β≥160.

Finally, advantageously, the remote control device, using artificial intelligence, makes it possible to evaluate and determine the contents, methods and timing of the projection of digital contents, analyzing the data of vehicular and pedestrian flows, the necessary and sufficient energy consumption, the meteorological conditions, lighting conditions, the production cost of the contents compared to the operating value of the system, etc.

1. Adjustable modular and digital photovoltaic cladding system (1), designed to produce electricity obtained from solar energy and to project digital contents, on a surface of a building to be covered, characterized in that said system (1) is capable of rotating by an angle a with 0°<α<360°, thus allowing a coating of external and roofing surfaces, with variable dimensions, extensions and inclinations, said system (1) comprising:
a plurality of LEDs (10) arranged on a first plurality of horizontal bars (100);
at least one strip of photovoltaic cells (20), arranged on a front surface of a second plurality of horizontal bars (200);
a plurality of detection and control sensors, designed to control brightness, contrast and chromatic range of said plurality of LEDs (10);
an aluminum perimeter structure (2);
said first plurality of horizontal bars (100), internally connected with each end to said perimeter structure (2) by means of a joint element (3) and equipped with at least one movement device capable of inducing a slow rotation of each of said first plurality of horizontal bars (100) by an angle a, included in a range 0°<α<360°, and provided on the front surface with a plurality of holes designed to enable housing said plurality of LEDs (10);
said second plurality of horizontal bars (200), internally connected with each end to said perimeter structure (2) by said joint element (3), preferably made of Teflon®, and equipped with said movement device capable of inducing a slow rotation of each plurality of horizontal bars by an angle a, included in a range 0°<α<360°, and provided on a front surface of the strip of photovoltaic cells.

2. System (1) according to claim 1, characterized in that it further comprises:
a remote control device capable of regulating and remotely controlling, using Al technology, the plurality of sensors, and each movement device, enabling a rotation of said first (100) and of said second (200) plurality of horizontal bars and consequently of said strip of photovoltaic cells (20) and of said plurality of LEDs (10) according to a plurality of factors, such as weather conditions, direct or indirect sunlight, etc.;
at least one insulated compartment arranged on the back surface of said first (100) and second (200) plurality of horizontal bars designed to contain a plurality of electrical elements and devices dedicated to remote management.

3. System (1) according to claim 1, characterized in said first plurality of bars (100) and said second plurality of bars (200) are arranged alternately, enabling an independent rotation, with concordant or discordant rotation direction, of each of said plurality of LEDs (10), and of each of said strip of photovoltaic cells (20) arranged respectively on said first (100) and on said second (200) plurality of horizontal bars.

4. System (1) according to claim 1, characterized in that it further comprises:
at least one transparent photovoltaic module;
a plurality of bars arranged on the back surface of the transparent photovoltaic module, internally connected with each end to the perimeter structure by said joint element (3), and equipped with said movement device capable of inducing a slow rotation of each plurality of horizontal bars by said angle a, included in a range 0°<α<360°, and consequently inducing a rotation of said transparent photovoltaic module.
